(19) United States
(12) Patent Application Publication
(10) Pub. No.: US 2025/0056996 A1
(43) Pub. Date: Feb. 13, 2025

(54) ORGANIC LIGHT EMITTING DIODE DISPLAY AND OPERATING METHOD THEREOF

(71) Applicant: LG ELECTRONICS INC., Seoul (KR)

(72) Inventor: Yong Su YOO, Seoul (KR)

(73) Assignee: LG ELECTRONICS INC., Seoul (KR)

(21) Appl. No.: 18/533,049

(22) Filed: Dec. 7, 2023

(30) Foreign Application Priority Data
Aug. 9, 2023 (KR) 10-2023-0104451

(51) Int. Cl. H10K 59/35; G09G 3/20

(52) U.S. Cl. CPC H10K 59/351; G09G 3/2003; G09G 2300/0452; G09G 2320/0626

(57) ABSTRACT

An object of the present disclosure is to prevent burn-in of a display panel by using a combination of RGBW data maintaining the same color and brightness as an original image.

### CROSS-REFERENCE TO RELATED APPLICATION

Pursuant to 35 U.S.C. § 119, this application claims the benefit of earlier filing date and right of priority to Korean Application No. 10-2023-0104451, filed on Aug. 9, 2023, the contents of which are all incorporated by reference herein in its entirety.

### TECHNICAL FIELD

The present invention relates to an organic light emitting diode display and an operating method thereof, and more particularly, to preventing deterioration of the organic light emitting diode display.

### BACKGROUND ART

Recently, various types of display devices have appeared. Among them, an organic light emitting diode display (hereinafter, referred to as an “OLED display device”) is widely used. Since the OLED device is a self-luminous device, it consumes less power and can be manufactured thinner than a liquid crystal display device requiring a backlight. In addition, the OLED device has advantages of a wide viewing angle and fast response speed.

In a general organic light emitting diode display, red (R), green (G), and blue (B) sub-pixels are configured as one unit pixel, and displays one image of various colors through the three sub-pixels.

If a still image is displayed for a long time, a cumulative light emission time between pixels is different, and thus a difference in light emission capability between pixels at a current time occurs.

As a result, if a still image is displayed for a long time and then changed to another image, the viewer sees an image in which the afterimage of the previous image is combined on a new image, resulting in inconvenience for the user to view the image.

Conventionally, there is a technique of changing image data of pixel having a large cumulative light emission time to solve this problem, but this causes a problem in that a displayed image is distorted.

In addition, there is a conventional technique for lowering the degree of an afterimage through a low pass filter (LPF), but this also has a problem of distorting the displayed image.

### DISCLOSURE

### Technical Problem

An object of the present disclosure is to prevent burn-in of a display panel by using a combination of RGBW data maintaining the same color and brightness as an original image.

An object of the present disclosure is to prevent a rapid brightness change occurring at a boundary between a still image and a background image by using a combination of RGBW data maintaining the same color and brightness as the original image.

### Technical Solution

An organic light emitting diode (OLED) display device according to an embodiment of the present disclosure may comprise: a display panel configured to display an image and includes a plurality of pixels, wherein each of the plurality of pixels including a red sub-pixel, a green sub-pixel, a blue sub-pixel, and a white sub-pixel; and a processor configured to: obtain a first red data value, a first green data value, and a first blue data value based on the image: select one among a plurality of data combinations for a pixel having the same brightness and color as the image: convert each of the first red data value, the first green data value, and the first blue data value into a second red data value, a second green data value, a second blue data value, and a first white data value corresponding to the data combination: apply the second red data value to the red sub-pixel: apply the green sub-pixel to the second green data value: apply the blue sub-pixel to the second blue data value; and apply the first white data value to the white sub-pixel.

An operating method of an organic light emitting diode (OLED) display device including a display panel configured to display an image and includes a plurality of pixels, wherein each of the plurality of pixels including a red sub-pixel, a green sub-pixel, a blue sub-pixel, and a white sub-pixel, according to an embodiment of the present disclosure, may comprise: obtaining a first red data value, a first green data value, and a first blue data value based on the image: selecting one among a plurality of data combinations for a pixel having the same brightness and color as the image; converting each of the first red data value, the first green data value, and the first blue data value into a second red data value, a second green data value, a second blue data value, and a first white data value corresponding to the data combination; applying the second red data value to the red sub-pixel: applying the green sub-pixel to the second green data value: applying the blue sub-pixel to the second blue data value; and applying the first white data value to the white sub-pixel.

### Advantageous Effects

According to various embodiments of the present disclosure, a burn-in phenomenon is prevented and a lifespan of a sub-pixel is increased by distributing a load so as not to overload a specific sub-pixel.

In addition, according to various embodiments of the present disclosure, afterimage and deterioration of specific sub-pixel in an OLED device can be prevented without changing the brightness and color of pixel.

In addition, a sudden brightness change occurring at the boundary between the still image and the background image may be prevented, thereby improving viewing experience.

### DESCRIPTION OF DRAWINGS

FIG. 1 is a diagram for explaining a configuration of an organic light emitting diode display device according to an exemplary embodiment of the present invention.

FIG. 2A is a diagram for explaining how afterimages occur.

FIGS. 2B and 2C are diagrams for explaining problems of a method for preventing afterimages according to the prior art.

FIG. 3 is a flowchart illustrating an operating method of an organic light emitting diode display device according to an exemplary embodiment of the present invention.

FIG. 4 is a diagram for explaining a conventional method of extracting data values of W sub-pixel.

FIG. 5 is a diagram illustrating a plurality of data combinations in which color and brightness of an image output through a unit pixel are not damaged according to an embodiment of the present disclosure.

FIG. 6 is a diagram for explaining a process of selecting one of a plurality of data combinations for R/G/B/W sub-pixels according to an embodiment of the present disclosure.

FIG. 7A is a diagram explaining that brightness of sub-pixels rapidly changes at a boundary between a content image and a background image due to afterimage in an existing display device.

FIG. 7B is a diagram explaining a process of gradually changing the brightness of sub-pixels at a boundary between a content image and a background image according to an embodiment of the present disclosure.

FIGS. 8 and 9 are diagrams illustrating the gradual brightness of sub-pixels at a boundary between a still image and a background image.

### BEST MODE

Hereinafter, embodiments relating to the present disclosure will be described in detail with reference to the drawings. The suffixes “module” and “unit” for components used in the description below are assigned or mixed in consideration of easiness in writing the specification and do not have distinctive meanings or roles by themselves.

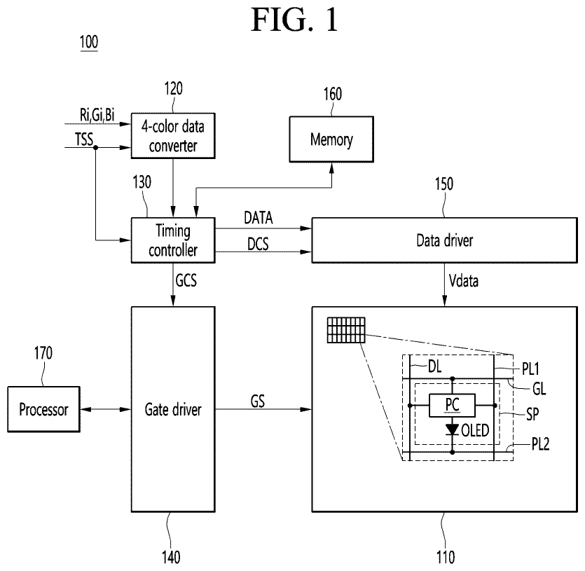

FIG. 1 is a diagram for explaining a configuration of an organic light emitting diode display device according to an exemplary embodiment of the present invention.

Referring to FIG. 1, the organic light emitting diode display device 100 includes a display panel 110, a 4-color data converter 120, a timing controller 130, a gate driver 140, a data driver 150, a memory 160 and a processor 170.

The display panel 110 may include a plurality of sub-pixels (SPs). A plurality of sub-pixels may be formed in a pixel area defined by a plurality of gate lines GL and a plurality of data lines DL that cross each other.

In the display panel 110, a plurality of driving power lines PL are formed parallel to each of the plurality of data lines DL to supply a driving voltage.

Each of the plurality of sub-pixels may be any one of a red sub-pixel, a green sub-pixel, a blue sub-pixel, and a white sub-pixel.

One unit pixel displaying one image may include a red sub-pixel, a green sub-pixel, a blue sub-pixel, and a white sub-pixel.

Each of the plurality of sub-pixels SP may include an organic light emitting diode (OLED) and a pixel circuit PC.

The OLED is connected between the pixel circuit PC and the driving power line PL2 and emits light in proportion to the amount of data current supplied from the pixel circuit PC, thereby emitting light of a predetermined color.

To this end, the OLED may include an anode electrode (or pixel electrode) connected to the pixel circuit PC, a cathode electrode (or reflective electrode) connected to the driving power supply line PL2, and a light emitting cell that is formed on between the anode electrode and the cathode electrode and emits light of any one color among red, green, blue, and white.

The light emitting cell may have a hole transport layer/organic light emitting layer/electron transport layer structure or a hole injection layer/hole transport layer/organic light emitting layer/electron transport layer/electron injection layer structure.

A functional layer for improving at least one of light emitting efficiency or lifetime of the organic light emitting layer may be additionally formed in the light emitting cell.

The pixel circuit PC supplies a data current corresponding to a data voltage Vdata supplied to a data line DL from the data driver 150 to the OLED in response to a gate signal GS of gate-on voltage level supplied to a gate line GL from the gate driver 140.

The data voltage Vdata has a voltage value in which deterioration characteristic of the OLED is compensated for.

The pixel circuit PC includes a switching transistor, a driving transistor, and at least one capacitor formed on a substrate by a thin film transistor forming process.

The switching transistor and driving transistor may be a-Si TFT, poly-Si TFT, oxide TFT, or organic TFT.

The switching transistor may supply the data voltage Vdata supplied to the data line DL to the gate electrode of the driving transistor according to the gate signal of the gate-on voltage level supplied to the gate line.

The driving transistor is turned on according to the gate-source voltage including the data voltage Vdata supplied from the switching transistor, thereby controlling the amount of current flowing from the driving voltage line PL1 to the OLED.

The 4-color data conversion unit 120 may generate a data provided to the unit pixel of the display panel 110 based on a timing synchronization signal (TSS) input from an external system body (not shown) or a graphics card (not shown) and 3-color input data (Ri, Gi and Bi).

The 4-color data converter 120 may generate four-color data (R, G, B, and W) of red, green, blue, and white to be supplied to each of a red sub-pixel, a green sub-pixel, a blue sub-pixel, and a white sub-pixel constituting a unit pixel based on the timing synchronization signal TSS and the three-color input data Ri, Gi, and Bi.

The generated four-color data (R, G, B, and W) may be provided to the timing controller 130.

The 4-color data conversion unit 120 may further include a filter (not shown). The filter can remove the noise of 3-color input data.

For example, the filter may perform filtering on grayscale level of each of red data, green data, and blue data to remove noise of three-color input data. The filter may filter one or more of red data, green data, and blue data.

The 4-color data converter 120 may be included in the timing controller 130.

The timing controller 130 may control driving timing each of the gate driver 140 and the data driver 150 based on a timing synchronization signal TSS input from an external system body (not shown) or a graphics card (not shown).

The timing controller 130 may generate a gate control signal GCS and a data control signal DCS based on a timing synchronization signal TSS such as a vertical synchronization signal, a horizontal synchronization signal, a data enable signal, and a dot clock.

The timing controller 130 may control the driving timing of the gate driver 140 through the gate control signal GCS, and control the driving timing of the data driver 150 through the data control signal DCS to be synchronized therewith.

The timing controller 130 may accumulated the data (R, G, B, and W) of each sub-pixel SP supplied from the 4-color data conversion unit 120 into in each sub-pixel SP unit for each frame or accumulation period set at a constant period and store it in the memory 160.

The gate driver 140 may generate a gate signal GS corresponding to the display order of image based on the gate control signal GCS provided from the timing controller 130, and supply the generated gate signal GS to a corresponding gate line GL.

The gate driver 140 is formed in the form of a plurality of integrated circuits (ICs) or directly formed on the substrate of the display channel 100 together with a process of forming a transistor of each sub-pixel (SP) and may be connected to one side or both sides of a plurality of gate lines (GLs).

The data driver 150 may receive pixel data DATA and a data control signal DCS from the timing controller 130.

The data driver 150 may receive a plurality of reference gamma voltages from an external reference gamma voltage supplier (not shown).

The data driver 150 may convert the pixel data DATA into an analog data voltage Vdata based on the data control signal DCS and a plurality of reference gamma voltages.

The data driver 150 may supply the converted data voltage Vdata to the data line DL of the corresponding sub-pixel SP. Accordingly, each unit pixel constituting the display panel 110 emits light from the corresponding organic light emitting element OLED by the data current based on the data voltage Vdata supplied to each sub-pixel SP, thereby displaying a predetermined image.

For each unit pixel, only three sub-pixels including a white sub-pixel among red, green, blue, and white sub-pixels may be driven, or all four sub-pixels may be driven.

The data driver 150 may be formed in the form of a plurality of integrated circuits (ICs) and connected to one side or/and both sides of the data line DL.

The timing controller 130 may control operation of the 4-color data converter 120, the gate driver 140, the data driver 150, and the memory 160.

Meanwhile, since the organic light emitting diode display device 100 shown in FIG. 1 is only one embodiment of the present invention. Some of the illustrated components may be integrated, added, or omitted according to specifications of the organic light emitting diode display device 100 that is actually implemented.

For example, the 4-color data conversion unit 120 and the timing controller 130 are configured as one control unit, or the 4-color data conversion unit 120, the timing controller 130, the gate driver 140 and the data driver 150 may be composed of one control unit (not shown).

The processor 170 may control overall operation of the organic light emitting diode display device 100.

The processor 170 may control operations of the display panel 110, the four-color data 120, the timing controller 130, the gate driver 140, the data driver 150, and the memory 160.

In another example, the processor 170 is not separately provided, and a configuration including a 4-color data conversion unit 120, a timing controller 130, a gate driver 140, and a data driver 150 may be a processor.

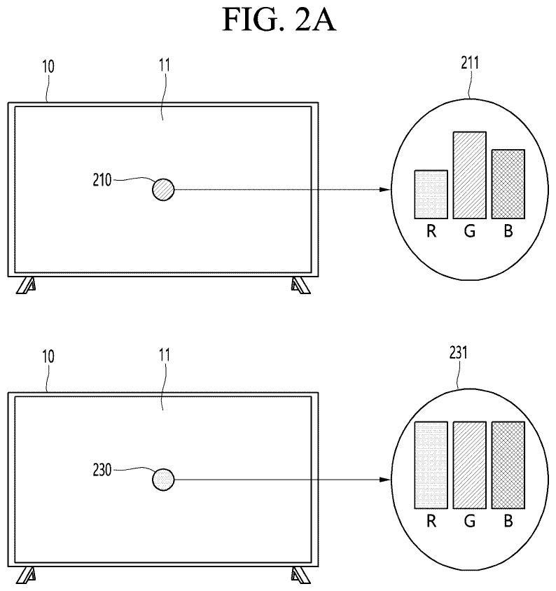

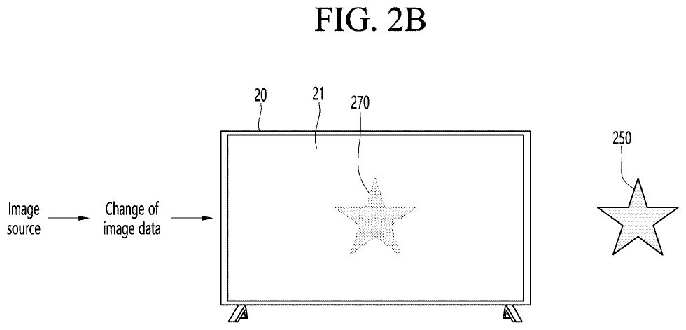

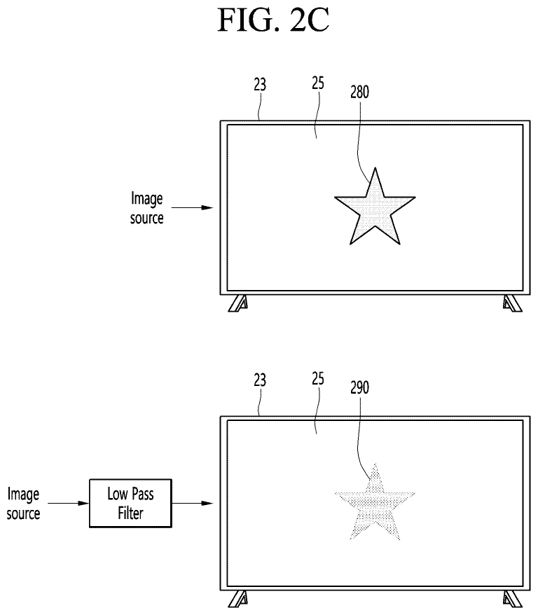

FIG. 2A is a diagram for explaining how afterimages occur, and FIGS. 2B and 2C are diagrams for explaining problems of a method for preventing afterimages according to the prior art.

Referring to FIG. 2A, the display device 10 displays a content image 210 on the display panel 11.

One pixel constituting the content image 210 has a first RGB data combination 211.

After the content image 210 is displayed for a long time, if the content image 210 is changed to a white image, an afterimage 230 corresponding to the content image 210 is displayed on the display panel 11.

This is because the light emitting capability of the pixel is affected by the cumulative light emission amount of the pixel due to the material limitation of the pixel.

That is, if a still image is displayed for a long time, a cumulative amount of light emission between pixels is different, resulting in a difference in light emission capability between pixels. Due to this, if a still image is displayed for a long time and then changed to another image, the user watches an image in which the afterimage of the previous still image is combined on the new image, which interferes with viewing.

FIG. 2B is a diagram illustrating a conventional technique of changing data of an input image source in order to solve the above afterimage problem.

The display device 20 calculates and stores the cumulative light emission time (or accumulated emission amount) for each pixel. The display device 20 manages the cumulative light emission time of each of the pixels.

If there is a difference in the cumulative light emission time between pixels, the display device 20 makes pixels with a large cumulative light emission time darker than the brightness of the original image data, or makes pixels with a small cumulative light emission time brighter than the brightness of the original image data.

However, in this method, since the original image 250 is distorted and the distorted image 270 is displayed on the display panel 21, the user's viewing experience is still disturbed.

FIG. 2C is a diagram illustrating a conventional technique of passing an input image source through a low pass filter (LPF) to solve the afterimage problem.

That is, the display device 23 gently changes the brightness distribution of adjacent pixels by passing the LPF through the input image source.

However, this method also distorts the original image 280 blurry and displays the distorted image 290 on the display panel 25, which still interferes with the user's viewing experience.

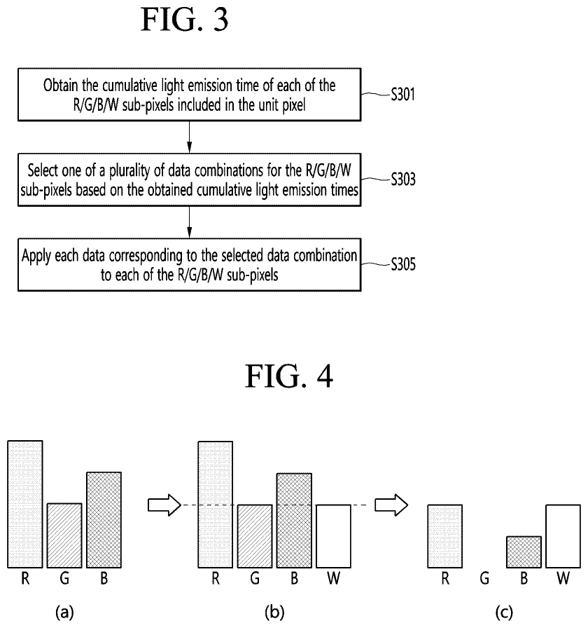

Next, referring to FIG. 3, an operating method of an OLED display device according to an exemplary embodiment of the present invention will be described.

In addition, the following description will be made in conjunction with the configuration of the OLED display device 100 described with reference to FIG. 1.

Hereinafter, the organic light emitting diode display device 100 may be referred to as a display device.

FIG. 3 is a flowchart illustrating an operating method of an organic light emitting diode display device according to an exemplary embodiment of the present invention.

Referring to FIG. 3, the processor 170 of the display device 100 may obtain the cumulative light emission time of each of the R/G/B/W sub-pixels included in the unit pixel (S301).

The processor 170 may calculate the time during which the current is supplied to each sub-pixel as the emission time of the sub-pixel. The processor 170 may calculate the cumulative light emission time of each sub-pixel up to the current point of time by counting the time during which the current is supplied to each sub-pixel.

The processor 170 may calculate the cumulative light emission time of each sub-pixel as the time for the data driver 150 to supply the data voltage Vdata to each sub-pixel.

The cumulative light emission time may be converted into a normalized cumulative emission amount.

The processor 170 may calculate a first cumulative light emission time of R (Red) sub-pixel, a second cumulative light emission time of G (Green) sub-pixel, a third cumulative light emission time of B (Blue) and the fourth cumulative light emission time of the W (White) sub-pixel constituting one unit pixel.

The processor 170 may store the first accumulated light emission time, the second accumulated light emission time, the third accumulated light emission time, and the fourth accumulated light emission time in the memory 160.

The processor 170 may calculate the first cumulative light emission time, the second cumulative light emission time, the third cumulative light emission time, and the fourth cumulative light emission time at regular time interval, and store the calculated results in the memory 160.

The memory 160 may be an image frame memory for storing image frames.

The processor 170 may select one of a plurality of data combinations for the R/G/B/W sub-pixels based on the acquired cumulative light emission times (S303).

Each of the plurality of data combinations has the same color and brightness of the input image (or original image) input to the display panel 110, but the R data value (the data value of the R sub-pixel), the G data value (the data value of the G sub-pixel), B data value (data value of sub-pixel B) and W data value (data value of sub-W pixel) may be different from each other.

The W data value may be automatically determined according to the R data value, the G data value, and the B data value.

A combination of a plurality of data of a unit image output through a unit pixel will be described.

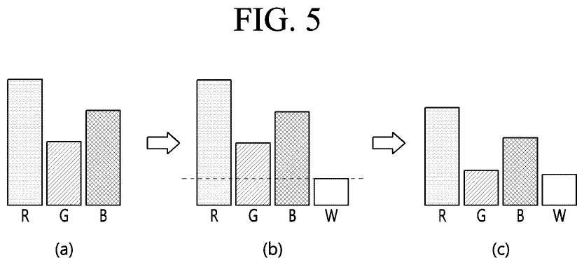

FIG. 4 is a diagram illustrating a conventional method of extracting data value of W sub-pixel, and FIG. 5 is a diagram illustrating a plurality of data combinations in which color and brightness of an image output through a unit pixel are not damaged according to an embodiment of the present disclosure.

Referring to (a) of FIG. 4, R data value, G data value, and B data value are shown.

As shown in (b) of FIG. 4, the W data value is determined as the smallest G data value among the R data value, the G data value, and the B data value.

After that, each of the remaining R data value, G data value, and B data value is determined as a value obtained by subtracting the W data value from the original data value, as shown in (c) of FIG. 4.

That is, R/G/B/W data values of 4 colors from R/G/B data values of 3 colors can be calculated by the following [Equation 1].

$${W}_{OUT} = MIN [ {RGB}_{IN} ] \\ {RGB}_{OUT} = {RGB}_{IN} - {W}_{OUT} \qquad [ Equation 1 ]$$

Referring to (a) of FIG. 5, the same R data value, G data value, and B data value as (a) of FIG. 4 are shown.

If the W data value determined in (b) of FIG. 4 is set to a slightly smaller value as in (b) of FIG. 5, each of the R data value, the G data value, and the B data value is slightly larger than (b) of FIG. 4.

At this time, the brightness and color of the unit pixel are not changed. This is because the reduced brightness of the W sub-pixel is compensated for by the brightness of the R/G/B sub-pixels.

In addition, the sum of the R data value, the G data value, and the B data value can be replaced with the W data value, so that the color of the unit pixel is not changed compared to the original image.

The number of R/G/B/W data combinations that do not damage the brightness and color of the original image output through the unit pixel may be the same as the W data value.

Referring to (c) of FIG. 5, if the W data value is set to a larger value than in (b) of FIG. 5, each of the R data value, the G data value, and the B data value is slightly larger than (b) of FIG. 5.

In this way, a plurality of data combinations that do not damage the brightness and color of the original image can be generated.

Again, FIG. 3 is described.

The processor 170 may calculate difference values of two cumulative light emission times among the first cumulative light emission time of the sub-R pixel, the second cumulative light emission time of the sub-G pixel, the third cumulative light emission time of the sub-B pixel, and the fourth cumulative light emission time of the sub-W pixel.

In an embodiment, the processor 170 may select a data combination that minimizes the sum of the difference values while maintaining the color and brightness of the input image (or original image).

In another embodiment, if the difference value between the cumulative light emission times between the two sub-pixels is equal to or greater than a predetermined value, the processor 170 may select one among a plurality of data combinations to reduce the difference value to less than a predetermined value while maintaining the color and brightness of the original image.

Accordingly, the lifetime of each sub-pixel becomes similar, so that afterimage can be prevented.

In another embodiment, the processor 170 may select a data combination to reduce the data value of the corresponding sub-pixel and increase the data value of each of the remaining sub-pixels while maintaining the color and brightness of the original image, if there is a sub-pixel exceeding a preset time among the first cumulative light emission time of the R sub-pixel, the second cumulative light emission time of the G sub-pixel, the third cumulative light emission time of the B sub-pixel, and the fourth cumulative light emission time of the W sub-pixel.

If there are two or more sub-pixels exceeding a preset time, a data combination may be selected such that data values of the corresponding sub-pixels are reduced and data values of each of the remaining sub-pixels are increased.

In another embodiment, the processor 170 may select a data combination to increase the data value of the corresponding sub-pixel and to decrease the data value of each of the remaining sub-pixels while maintaining the color and brightness of the original image if there is a sub-pixel whose duration is less than a preset time among the first cumulative light emission time of the R sub-pixel, the second cumulative light emission time of the G sub-pixel, the third cumulative light emission time of the B sub-pixel, and the fourth cumulative light emission time of the W sub-pixel.

If there are two or more sub-pixels for less than a preset time, a data combination may be selected such that data values of the corresponding sub-pixels are increased and data values of the remaining sub-pixels are decreased.

In another embodiment, the processor 170 may randomly select one of a plurality of data combinations maintaining the color and brightness of the original image. In this case, unlike other embodiments, a separate operation is not required, and the load applied to the processor 170 can be reduced.

In another embodiment, the processor 170 may selects a data combination that reduces the data value of sub-pixel B and increases the data values of the remaining sub-pixels among a plurality of data combinations while maintaining the color and brightness of the original image. Since the lifetime of sub-B pixel is generally shorter than that of other sub-pixels, a data combination may be selected in a direction that maximizes the lifespan of sub-B pixel.

Meanwhile, step S303 may be performed by the 4-color data conversion unit 120 instead of the processor 170.

That is, the 4-color data converter 120 may select one of a plurality of data combinations for the R/G/B/W sub-pixels based on the acquired cumulative light emission times.

The 4-color data conversion unit 120 may convert each of the R/G/B data values into each of the R/G/B/W data values corresponding to the selected data combination.

The processor 170 may apply each data corresponding to the selected data combination to each of the R/G/B/W sub-pixels (305).

The processor 170 may control the 4-color data converter 120 to provide the converted R/G/B/W data values to the timing controller 130.

The processor 170 may convert the first red data value, the first green data value, and the first blue data value based on the input image into the second red data value, the second green data value, the second blue data value corresponding to the selected data combination and a first white data value.

The processor 170 may apply the second red data value to the red sub-pixel, the second green data value to the green sub-pixel, the second blue data value to the blue sub-pixel, and the first white data value to the white sub-pixel, respectively.

The timing controller 130 may provide pixel data including R/G/B/W data values to the data driver 150.

The data driver 150 may convert pixel data into an analog data voltage and supply the converted data voltage to a data line of a corresponding sub-pixel.

Accordingly, as the OLED emits light by the data current based on the data voltage supplied to each sub-pixel, the unit pixel constituting the display panel 110 may display a predetermined image.

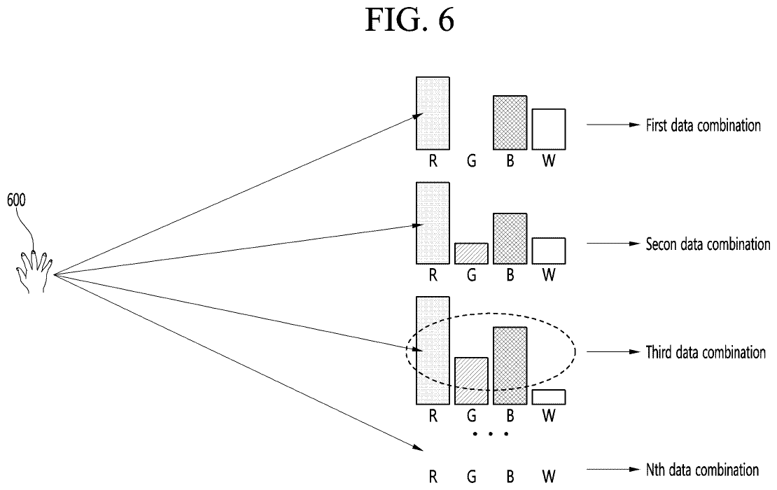

FIG. 6 is a diagram for explaining a process of selecting one of a plurality of data combinations for R/G/B/W sub-pixels according to an embodiment of the present disclosure.

Referring to FIG. 6, a data combination including data values of each of the R sub-pixel, G sub-pixel, B sub-pixel, and W sub-pixel constituting the unit pixel of the image 600 is shown.

That is, the number of a plurality of data combinations may be N to maintain the brightness and color of the unit image displayed by the unit pixel.

The processor 170 may select one of a plurality of data combinations in which the brightness and color of the original image are maintained.

In an embodiment, the processor 170 may select a data combination that darkens the brightness of a sub-pixel having the largest cumulative light emission time among a plurality of data combinations in which the brightness and color of the original image are maintained.

That is, the processor 170 may select a data combination that reduces the brightness of a sub-pixel having the largest cumulative light emission time among a plurality of data combinations in which the brightness and color of the original image are maintained.

In another embodiment, the processor 170 may select a data combination that brightens the brightness of a sub-pixel having the smallest cumulative light emission time among a plurality of data combinations in which the brightness and color of the original image are maintained.

That is, the processor 170 may select a data combination that increases the brightness of a sub-pixel having the smallest cumulative light emission time among a plurality of data combinations maintaining the brightness and color of the original image.

In another embodiment, the processor 170 may randomly select a data combination among a plurality of data combinations maintaining the brightness and color of the original image.

As described above, according to an embodiment of the present disclosure, a data combination may be selected in consideration of the cumulative light emission time of each sub-pixel.

Accordingly, not only is the original image not distorted, but the lifespan of the sub-pixels constituting the unit pixel is evened, so that afterimage is prevented.

Meanwhile, whether the embodiment of FIG. 3 is applied to the display device can be determined through the following process.

1-1. The display device 100 displays a test still image.

1-2. After that, the user selects a specific pixel among a plurality of pixels displaying the test still image.

1-3. A user observes the brightness of each of the R/G/B/W sub-pixels constituting a specific pixel using a magnifying glass or a microscope.

1-4. After a certain period of time (example, 5 minutes) has elapsed, it is observed whether the brightness of each of the R/G/B/W sub-pixels constituting a specific pixel is changed.

1-5. If the brightness of each of the R/G/B/W sub-pixels constituting a specific pixel is changed while displaying the test still image, it can be considered that an embodiment of the present disclosure in which the selected data combination is applied to the R/G/B/W sub-pixels by selecting one of a plurality of data combinations maintaining the brightness and color of the original image is selected.

Whether the embodiment of FIG. 3 is applied to the display device can be determined through the following process.

2-1. The display device 100 prepares a first test still image and a second test still image. Each of the first test still image and the second test still image includes partial images having the same brightness and color.

2-2. The first test still image is displayed and left for a certain period of time.

2-3. Observe the brightness of each R/G/B/W sub-pixel of the partial image mentioned in 2-1 with a magnifying glass or microscope.

2-4. The second test still image is displayed and left for a certain period of time.

2-5. Observe the brightness of each R/G/B/W sub-pixel of the partial image mentioned in 2-1 with a magnifying glass or microscope.

2-6. If the brightness of each of the R/G/B/W sub-pixels observed in 2-3 and 2-5 is different from each other, it can be considered that the embodiment of the present disclosure is applied.

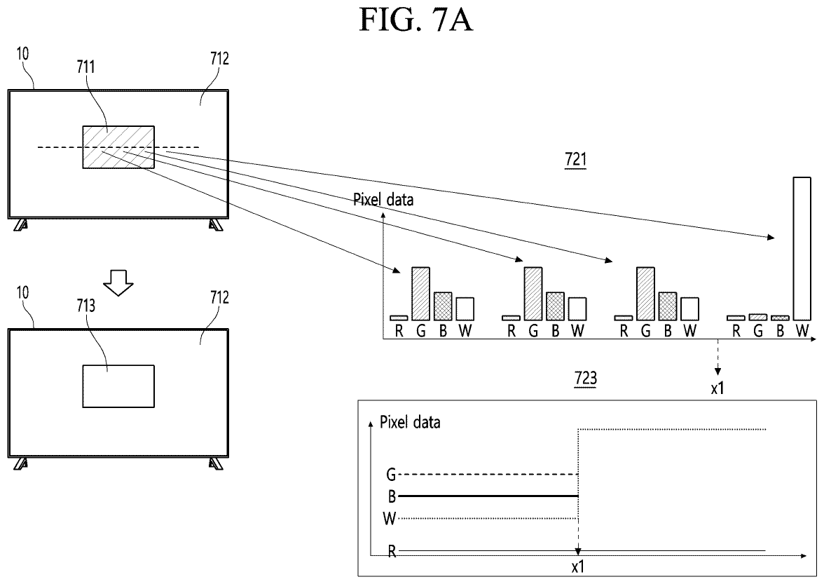

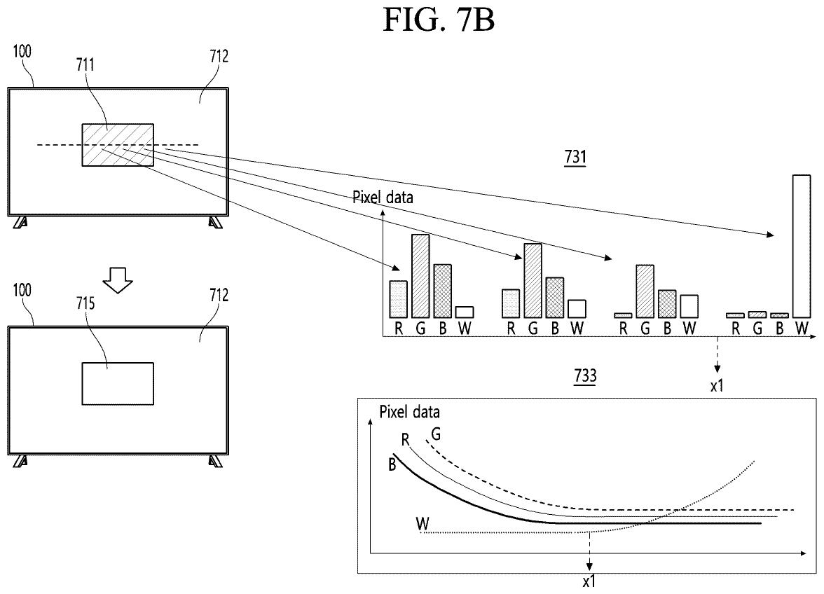

FIG. 7A is a diagram explaining that the brightness of sub-pixels is rapidly changed at the boundary between a content image and a background image due to afterimages in an existing display device, and FIG. 7B is a diagram explaining a process of gradually changing the brightness of sub-pixels at a boundary between a content image and a background image according to an embodiment of the present disclosure.

Referring to FIG. 7A, the conventional display device 10 displays a rectangular image 711 having a rectangular shape and a background image 712 that is a white image.

After a certain amount of time has elapsed, the rectangular image 711 disappears and an afterimage 713 of the rectangular image 711 is displayed.

Also, referring to FIG. 7A, a first pixel distribution graph 721 representing data of each sub-pixel with respect to the horizontal position (horizontal coordinate) of the display device 10 in the form of a bar graph and a second pixel distribution graph 723 representing data of each sub-pixel with respect to the horizontal position of the display device 10 in the form of line are shown.

Referring to the first pixel distribution graph 721 and the second pixel distribution graph 723, it can be seen that the brightness of sub-pixels rapidly changes from the boundary position (x1) between the rectangular image 711 and the background image 712 as a starting point.

Accordingly, it can be seen that the boundary of the generated afterimage 713 is also sharp.

As described above, according to the prior art, as the brightness of sub-pixels rapidly changes starting from the boundary position between the rectangular image 711 and the background image 713, the viewer also feels the afterimage 713 seriously.

Referring to FIG. 7B, the display device 100 according to an embodiment of the present disclosure displays a rectangular image 711 having a rectangular shape and a background image 712 that is a white image.

After a certain amount of time has elapsed, the rectangular image 711 disappears and an afterimage 715 of the rectangular image 711 is displayed.

If a still image such as the rectangular image 711 is sensed, the processor 170 may select a data combination that smoothes a change in brightness of each of the R/G/B/W sub-pixels from among a plurality of data combinations.

The plurality of data combinations may be combinations in which brightness and color of pixel are kept the same, but data values of sub-pixels are different from each other.

The processor 170 may select a data combination such that the brightness of sub-pixels becomes to be smoothly from the pixels of the square image 711 to the pixels of the background image 712.

The processor 170 to obtain a slope representing the degree of decrease in the data value of the corresponding sub-pixel based on the difference between the data value of the sub-pixel (one of the RGBW sub-pixels) constituting the pixel located in the center of the rectangular image 711 and the data value of the sub-pixel constituting the pixel located at the boundary position. Here, the selected sub-pixel may have the smallest data value.

The processor 170 decreases the data value of the selected sub-pixel toward the position of the background image 712 based on the center of the square image 711 according to the obtained gradient, and adjusts the data values of the remaining sub-pixels accordingly.

Accordingly, brightness distribution between corresponding sub-pixels of adjacent pixels may be smoothed.

Referring to FIG. 7B, according to an embodiment of the present disclosure, a third pixel distribution graph 731 representing data of each sub-pixel with respect to the horizontal position (horizontal coordinate) of the display device 100 in the form of a bar graph and a fourth pixel distribution graph 733 representing data of each sub-pixel with respect to the horizontal position of the device 100 in the form of a line are shown.

Referring to the third pixel distribution graph 731 and the fourth pixel distribution graph 733, it can be seen that the brightness of the sub-pixels starting from the boundary position (x1) between the square image 711 and the background image 712 is changed more smoothly compared to the first pixel distribution graph 721 and the second pixel distribution graph 723 of FIG. 7A.

Accordingly, it can be seen that the boundary of the generated afterimage 715 is also smooth.

As described above, according to an embodiment of the present disclosure, as the brightness of sub-pixels gradually changes starting from the boundary position between the square image 711 and the background image 712, the viewer feels the afterimage 713 less seriously.

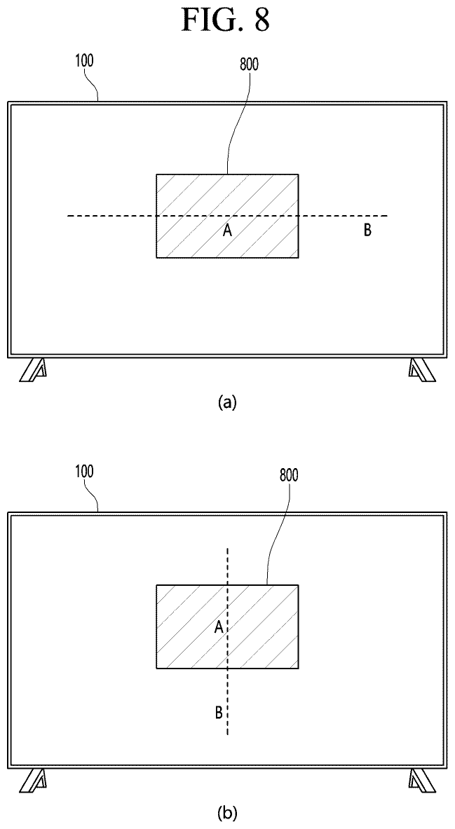

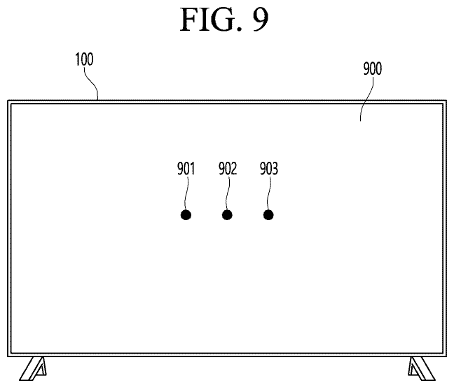

FIGS. 8 and 9 are diagrams illustrating the gradual brightness of sub-pixels at a boundary between a still image and a background image.

Referring to (a) and (b) of FIG. 8, the display device 100 displays a test still image 800.

After a certain amount of time (example, 5 minutes) has elapsed, the user observes the brightness of a specific sub-pixel with a magnifying glass or a microscope along a horizontal solid line in (a) or a vertical solid line in (b) of FIG. 8.

If the brightness of a specific sub-pixel of each pixel is gradually changed along a horizontal solid line or a vertical solid line, it may be considered that an embodiment in which a data combination that smooths out the change of the brightness of each of the R/G/B/W sub-pixels among a plurality of data combinations is applied while maintaining the brightness and color of the pixel are maintained.

Next, FIG. 9 will be described.

3-1. As shown in FIG. 9, the display device 100 displays an image pattern 900 of a single color on the entire screen.

3-2. A user observes each of a first pixel at a first point 901, a second pixel at a second point 902, and a third pixel at a third point 903 of the image pattern 900 with a magnifying glass or a microscope.

3-3. Even though the first pixel, the second pixel, and the third pixel have the same brightness and color, if the brightness of the R/G/B/W sub-pixels constituting the first pixel, the second pixel, and the third pixel are different, the embodiment of the disclosure may be considered applied.

Meanwhile, as shown in FIG. 9, if display device 100 may select data combination to have a similar distribution of R/G/B/W data values to each other in consideration of the color of adjacent pixel if displaying the image pattern 900 of the single color.

According to an embodiment of the present invention, the above-described method can be implemented as a processor-readable code in a medium on which a program is recorded. Examples of media readable by the processor include ROM, RAM, CD-ROM, magnetic tape, floppy disk, optical data storage, and the like.

What is claimed is:

1. An organic light emitting diode (OLED) display device, comprising:
a display panel configured to display an image and includes a plurality of pixels, wherein each of the plurality of pixels including a red sub-pixel, a green sub-pixel, a blue sub-pixel, and a white sub-pixel; and
a processor configured to:
obtain a first red data value, a first green data value, and a first blue data value based on the image;
select one among a plurality of data combinations for a pixel having the same brightness and color as the image;
convert each of the first red data value, the first green data value, and the first blue data value into a second red data value, a second green data value, a second blue data value, and a first white data value corresponding to the data combination;
apply the second red data value to the red sub-pixel;
apply the green sub-pixel to the second green data value;
apply the blue sub-pixel to the second blue data value; and
apply the first white data value to the white sub-pixel.

2. The OLED display device of claim 1, wherein the processor is further configured to:
obtain a first cumulative light emission time of the red sub-pixel, a second cumulative light emission time of the green sub-pixel, a third cumulative light emission time of the blue sub-pixel, and a fourth cumulative light emission time of the white sub-pixel; and
select a data combination based on the first accumulated light emission time, the second accumulated light emission time, the third accumulated light emission time, and the fourth accumulated light emission time.

3. The OLED display device of claim 2, wherein the processor is configured to:
select the data combination to increase the brightness of a sub-pixel having the smallest cumulative light emission time among the first cumulative light emission time, the second accumulated light emission time, the third accumulated light emission time, and the fourth accumulated light emission time.

4. The OLED display device of claim 2, wherein the processor is configured to:
select the data combination to reduce the brightness of a sub-pixel having the largest accumulated light emission time among the first cumulative light emission time, the second accumulated light emission time, the third accumulated light emission time, and the fourth accumulated light emission time.

5. The OLED display device of claim 2, wherein the processor is further configured to:
calculate difference values between two cumulative light emission times among the first cumulative light emission time, the second cumulative light emission time, the third cumulative light emission time, and the fourth cumulative light emission time;
select the data combination such that a sum of the difference values is minimized.

6. The OLED display device of claim 2, wherein the processor is further configured to:
calculate a difference value between two cumulative light emission times among the first cumulative light emission time, the second cumulative light emission time, the third cumulative light emission time, and the fourth cumulative light emission time;
select the data combination to reduce the difference value to less than the predetermined value if the calculated difference value is greater than or equal to the predetermined value.

7. The OLED display device of claim 1, wherein the processor is further configured to:
randomly, select any one of the plurality of data combinations.

8. The OLED display device of claim 1, wherein the display panel is configured to display a still image and a background image,
the processor is configured to select the data combination such that the brightness of sub-pixel becomes smooth from the pixel of the still image to the pixel of the background image.

9. An operating method of an organic light emitting diode (OLED) display device including a display panel configured to display an image and includes a plurality of pixels, wherein each of the plurality of pixels including a red sub-pixel, a green sub-pixel, a blue sub-pixel, and a white sub-pixel, comprising:
obtaining a first red data value, a first green data value, and a first blue data value based on the image;
selecting one among a plurality of data combinations for a pixel having the same brightness and color as the image;
converting each of the first red data value, the first green data value, and the first blue data value into a second red data value, a second green data value, a second blue data value, and a first white data value corresponding to the data combination;
applying the second red data value to the red sub-pixel applying the green sub-pixel to the second green data value;
applying the blue sub-pixel to the second blue data value; and
applying the first white data value to the white sub-pixel.

10. The operating method of claim 9, further comprising:
obtaining a first cumulative light emission time of the red sub-pixel, a second cumulative light emission time of the green sub-pixel, a third cumulative light emission time of the blue sub-pixel, and a fourth cumulative light emission time of the white sub-pixel,
wherein the step of selecting the data combination comprises:
selecting a data combination based on the first accumulated light emission time, the second accumulated light emission time, the third accumulated light emission time, and the fourth accumulated light emission time.

11. The operating method of claim 10, wherein the step of selecting the data combination comprises:
selecting the data combination to increase the brightness of a sub-pixel having the smallest cumulative light emission time among the first cumulative light emission time, the second accumulated light emission time, the third accumulated light emission time, and the fourth accumulated light emission time.

12. The operating method of claim 10, wherein the step of selecting the data combination comprises:
selecting the data combination to reduce the brightness of a sub-pixel having the largest accumulated light emission time among the first cumulative light emission time, the second accumulated light emission time, the third accumulated light emission time, and the fourth accumulated light emission time.

13. The operating method of claim 10, further comprising:
calculating difference values between two cumulative light emission times among the first cumulative light emission time, the second cumulative light emission time, the third cumulative light emission time, and the fourth cumulative light emission time,
wherein the step of selecting the data combination comprises:
selecting the data combination such that a sum of the difference values is minimized.

14. The operating method of claim 10, further comprising:
calculating a difference value between two cumulative light emission times among the first cumulative light emission time, the second cumulative light emission time, the third cumulative light emission time, and the fourth cumulative light emission time,
wherein the step of selecting the data combination comprises:
selecting the data combination to reduce the difference value to less than the predetermined value if the calculated difference value is greater than or equal to the predetermined value.

15. The operating method of claim 9, wherein the step of selecting the data combination comprises:
randomly, selecting any one of the plurality of data combinations.
